(19) United States
(12) Patent Application Publication
(10) Pub. No.: US 2024/0417855 A1
(43) Pub. Date: Dec. 19, 2024

(54) SUBSTRATE SUPPORTING APPARATUS AND SUBSTRATE PROCESSING APPARATUS

(71) Applicant: ASM IP Holding B.V., Almere (NL)

(72) Inventors: Ippei Yanagisawa, Sagamihara-shi (JP); Takashi Hamaguchi, Kawasaki-shi (JP)

(21) Appl. No.: 18/739,563

(22) Filed: Jun. 11, 2024

Related U.S. Application Data
(60) Provisional application No. 63/472,839, filed on Jun. 14, 2023.

(51) Int. Cl. C23C 16/458

(52) U.S. Cl. CPC C23C 16/4584

(57) ABSTRACT

A substrate supporting apparatus includes: a susceptor configured for a substrate to be place on; and a moving mechanism that is connected to the susceptor and configured to rotate the susceptor about a central axis of the susceptor, the central axis extending in a vertical direction, wherein the moving mechanism is configured to move the susceptor further in a direction extending in an imaginary horizontal plane perpendicular to the central axis.

### CROSS-REFERENCE TO RELATED APPLICATIONS

This application claims priority to U.S. Provisional Patent Application Ser. No. 63/472,839 filed Jun. 14, 2023 titled SUBSTRATE SUPPORTING APPARATUS AND SUBSTRATE PROCESSING APPARATUS, the disclosure of which is hereby incorporated by reference in its entirety.

### FIELD OF INVENTION

The present invention relates to a substrate supporting apparatus and a substrate processing apparatus.

### BACKGROUND OF THE DISCLOSURE

Substrate processing apparatuses are widely used to process substrates, for example, to form thin films on a substrate. A CVD equipment is known as a substrate processing apparatus that forms a thin film by depositing a substance produced by a chemical reaction of raw material gases containing film components on the surface of a substrate to be processed (for example, a silicon wafer). The plasma CVD equipment is widely used as a CVD equipment. In the plasma CVD equipment, a raw material gas is put into a plasma state to generate active excited molecules, radicals, and ions, thereby promoting a chemical reaction. The plasma CVD equipment includes a wafer supporting apparatus for supporting a wafer to be subjected to film formation processing in a chamber. A shower head for supplying raw material gas to the inside of the chamber is arranged above the substrate supporting apparatus. Plasma is generated by applying a radio frequency (RF) voltage between the shower head and the substrate supporting apparatus.

CVD films deposited on wafers may have also been cured using UV radiation to speed up the manufacturing process while reducing the thermal history of the wafer. For example, in the UV processing apparatus described in U.S. Pat. No. 8,203,126B2, at least one of the UV lamp module and the substrate rotates during the curing process to generate a pattern that provides high intensity and uniform exposure on the substrate (wafer).

### SUMMARY OF THE DISCLOSURE

During film formation in a CVD equipment, variations occur in the distribution of plasma density, pumping efficiency, gas diffusion, etc. at each position on the substrate within the chamber. Therefore, it is difficult to uniform the film characteristics of the thin film formed on the substrate. Therefore, it is conceivable to uniform the film properties of the thin film by rotating the substrate supporting apparatus, for example, as in the UV processing device described in U.S. Pat. No. 8,203,126B2.

However, when the distribution of plasma density, pumping efficiency, gas diffusion, etc. takes a normal distribution, that is, when the peak of the distribution is near the center of the substrate, the film characteristics of the thin film to be deposited cannot be made uniform in the substrate radial direction even if the substrate supporting apparatus is rotated around the substrate central axis.

An object of the present invention is to provide a substrate supporting apparatus and a substrate processing apparatus capable of stably uniformizing the film properties of a thin film formed on a substrate.

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

### [First Aspect of Present Invention]

A substrate supporting apparatus including: a susceptor configured for a substrate to be place on; and a moving mechanism that is connected to the susceptor and configured to rotate the susceptor about a central axis of the susceptor, the central axis extending in a vertical direction, wherein the moving mechanism is configured to move the susceptor further in a direction extending in an imaginary horizontal plane perpendicular to the central axis.

### [Second Aspect of Present Invention]

The substrate supporting apparatus according to the first aspect, wherein the susceptor is configured to be stopped at any position within a movement range thereof extending in the direction extending in the horizontal plane.

### [Third Aspect of Present Invention]

The substrate supporting apparatus according to the first or the second aspect, wherein the moving mechanism includes: an external gear, tooth being placed side by side on an inner circumference thereof; and an internal gear connected to the susceptor, tooth being placed side by side on an outer circumference thereof, the internal gear being configured rotate in a state where the tooth and the tooth meshing with each other, wherein a number of teeth of the internal gear is less than a number of teeth of the external gear.

### [Fourth Aspect of Present Invention]

The substrate supporting apparatus according to the third aspect, wherein any point on the susceptor traces a trochoidal curved trajectory on the imaginary horizontal plane.

### [Fifth Aspect of Present Invention]

A substrate processing apparatus including: the substrate supporting apparatus according to any one of the first to the fourth aspects; and a chamber housing the susceptor.

### [Sixth Aspect of Present Invention]

A substrate processing apparatus including: the substrate supporting apparatus according to the third or the fourth aspect of the present invention; a chamber housing the susceptor; a lifting mechanism configured to move the susceptor vertically; and a drive source configured to drive the lifting mechanism.

### [Seventh Aspect of Present Invention]

The substrate processing apparatus according to the sixth aspect, wherein the external gear and the internal gear are placed outside the chamber.

### [Eighth Aspect of Present Invention]

The substrate processing apparatus according to the sixth or the seventh aspect, wherein the drive source further is further configured to rotate the internal gear.

### [Ninth Aspect of Present Invention]

The substrate processing apparatus according to any one the sixth to eighth aspect, wherein the internal gear is configured to repeat forward and reverse rotation within an angle range of 180° or less centered on a central axis of the internal gear in a rotation direction of the internal gear about the central axis.

### [Tenth Aspect of Present Invention]

The substrate processing apparatus according to the eighth or the ninth aspect, further including a gear mechanism configured to transmit a rotational driving force of the driving source to the internal gear, wherein the gear mechanism includes: an input shaft configured for the rotational driving force to be input; and a plurality of output shafts configured for the rotational driving force that is input to the input shaft and branched to be output, a plurality of sets of the susceptor and the movement mechanism are provided, and the internal gear of the moving mechanism of each of the sets is connected to each of the input shafts.

### [Eleventh Aspect of Present Invention]

The substrate processing apparatus according to the tenth aspect, further including a connecting member connecting the internal gear and the output shafts, wherein the output shaft has a vertical shaft part extending in a vertical direction, and the connecting member connects the internal gear and the vertical shaft part that are arranged eccentric to each other.

### [Twelfth Aspect of Present Invention]

The substrate processing apparatus according to the tenth or the eleventh aspect, wherein the gear mechanism includes: an input gear provided to the input shaft; a ring gear configured to mesh with the input gear; a gear housing fixed on the ring gear; a pinion shaft supported by the gear housing; a pair of pinion gears rotatably supported by the pinion shaft; and a pair of side gears configured to mesh with the pair of the pinion gears, and a pair of the output gears that are arranged coaxially with a central axis of the ring gear are provided, and each of the side gears is provided to each of the output gears.

### [Thirteenth Aspect of Present Invention]

The substrate processing apparatus according to the twelfth aspect, wherein a number of teeth of the ring gears is larger than a number of teeth of the input gear.

### [Fourteenth Aspect of Present Invention]

The substrate processing apparatus according to any one of the twelfth or the thirteenth aspect, wherein a number of teeth of the pinion gears is identical to a number of teeth of the side gears.

### [Fifteenth Aspect of Present Invention]

The substrate processing apparatus according to any one of the tenth to the fourteenth aspects, further including a lock mechanism configured to prevent rotation of one of the output shafts.

### [Sixteenth Aspect of Present Invention]

The substrate processing apparatus according to any one of the sixth to the fifteenth aspects, wherein the substrate processing apparatus is a CVD equipment configured to deposit a thin film on the substrate by a CVD method.

According to the substrate supporting apparatus and the substrate processing apparatus of the aspects of the present invention, the film characteristics of the thin film formed on the substrate can be stably made uniform.

### BRIEF DESCRIPTION OF THE DRAWING FIGURES

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

FIG. 1 is a longitudinal cross-sectional view showing an example of the chamber of the plasma CVD equipment according to one embodiment of the present invention.

FIG. 2 is a longitudinal cross-sectional view schematically and simply showing the plasma CVD equipment according to one embodiment of the present invention and a substrate supporting apparatus provided in the plasma CVD equipment.

The sub-panels (a) and (b) of FIG. 3 are plan views of the external gear and the internal gear of the movement mechanism, and for explaining the revolution and rotation of the internal gear.

FIG. 4A is a side view showing a simplified connection member.

FIG. 4B is other side view showing a simplified connection member.

FIG. 5 is a perspective view showing a simplified gear mechanism.

FIG. 6 is a perspective view showing a simplified gear mechanism and a lock mechanism.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include substrates in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

In this embodiment, an XYZ orthogonal coordinate system (three-dimensional orthogonal coordinate system) is appropriately set in each drawing, and each component will be described. In each figure, the Z-axis direction corresponds to the up-down direction (vertical direction). In the Z-axis direction, the +Z side corresponds to the upper side, and the −Z side corresponds to the lower side. Also, the X-axis direction and the Y-axis direction correspond to directions in which an imaginary horizontal plane (XY plane) perpendicular to the Z-axis direction extends. For example, the Y-axis direction corresponds to the front-rear direction, the +Y side corresponds to the rear side, and the −Y side corresponds to the front side. The X-axis direction corresponds to the left-right direction, the +X side corresponds to the right side, and the −X side corresponds to the left side. However, the Y-axis direction is not limited to this, and the Y-axis direction may be the left-right direction, and the X-axis direction may be the front-rear direction.

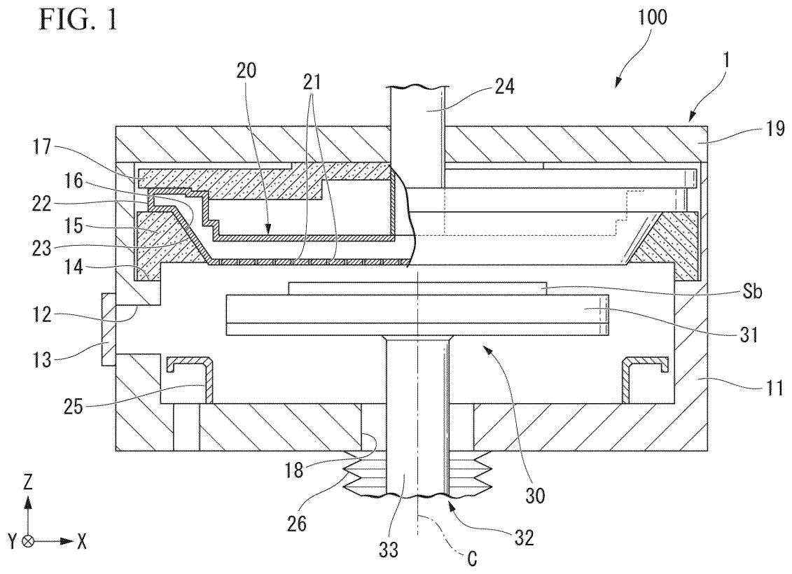

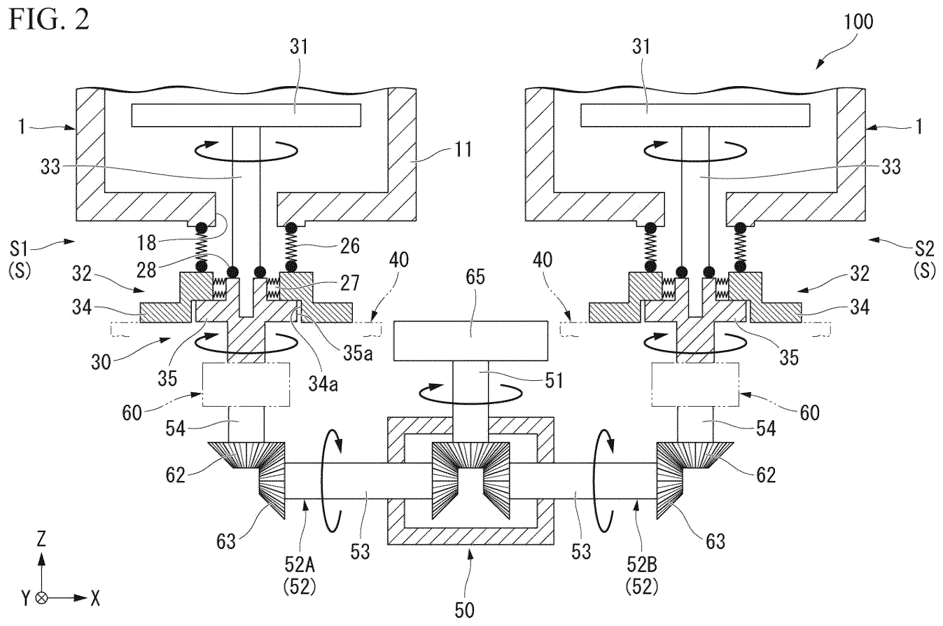

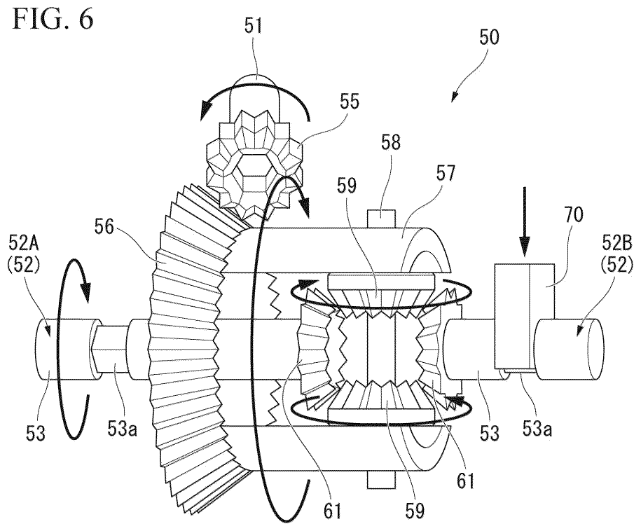

The substrate processing apparatus of the present embodiment is a CVD equipment for forming a thin film on a substrate (wafer) by CVD, specifically a plasma CVD equipment. As shown in FIGS. 1 and 2, the plasma CVD equipment 100 includes the chamber 1, the substrate supporting apparatus 30, the gear mechanism 50, the connecting member 60, the drive source 65, the lock mechanism 70 (see FIG. 6) and the lifting mechanism 40. In FIG. 2, the gear mechanism 50 is schematically shown in a simplified manner, and illustration of the shape of the connecting member 60 is omitted.

As shown in FIG. 1, the chamber 1 has a substantially cylindrical shape. The chamber 1 accommodates a later-described susceptor 31 of the substrate supporting apparatus 30. The chamber 1 has the chamber body 11, the lid member 19, the shower head fixing member 15, the shower head 20, the high frequency shielding plate 17, the gas supply pipe 24 and the gas exhaust pipe 25.

The chamber main body 11 and the lid member 19 are made of metal material. Aluminum, for example, can be used as this metal material. The chamber main body 11 has a cylindrical shape with a bottom. The lid member 19 is disc-shaped and closes the upper end portion of the chamber body 11. The chamber main body 11 has the entrance/exit 12, the door portion 13 and the recess portion 14.

The entrance/exit 12 is arranged on the side of the chamber body 11. The entrance/exit 12 is provided through the peripheral wall of the chamber body 11. A substrate Sb, which is the substrate to be processed, is carried into or out of the chamber 1 through the entrance/exit 12. The door portion 13 is configured to be able to open and close the doorway 12.

The recess portion 14 is arranged above the entrance/exit 12 on the inner surface of the peripheral wall of the chamber body 11. A shower head fixing member 15 is arranged in the recess portion 14. The showerhead fixing member 15 is a ring-shaped member having opening 16. The opening 16 is an inverted conical hole penetrating the shower head fixing member 15 in the vertical direction, and the inside diameter of the lower part is smaller than that of the upper part. As a material of the shower head fixing member 15, for example, a ceramic material such as Al₂O₃ can be used.

The shower head 20 has a disc shape and is hollow inside. The showerhead 20 has the vent holes 21. The vent holes 21 are arranged at the bottom of the showerhead 20. The showerhead 20 has the flange portion 22. The flange portion 22 is arranged on the upper portion of the showerhead 20. The outer diameter dimension of the flange portion 22 is larger than the inner diameter dimension of the opening 16 of the shower head fixing member 15. The showerhead 20 has an inverted truncated conical side surface 23 extending downward from the flange portion 22. The side surface 23 has a smaller outside diameter at the bottom than at the top. The side surface 23 of the showerhead 20 and the opening 16 of the showerhead fixing member 15 are fitted so as to be in close contact with each other. As a material of the shower head 20, for example, metal such as aluminum can be used.

The high frequency shielding plate 17 has a disc shape. A high frequency shielding plate 17 is arranged between the showerhead 20 and the lid member 19. The flange portion 22 of the showerhead 20 is sandwiched between the lower surface of the high frequency shielding plate 17 and the upper surface of the showerhead fixing member 15. As a material of the high-frequency shielding plate 17, for example, a ceramic material such as Al₂O₃ can be used.

The gas supply pipe 24 is vertically penetrated through the lid member 19 and connected to the upper center of the shower head 20. A raw material gas is supplied to the shower head 20 through the gas supply pipe 24. Furthermore, the raw material gas is supplied to the Substrate Sb in the chamber 1 through the ventilation holes 21 of the shower head 20. The gas exhaust pipe 25 is arranged at the bottom inside the chamber 1. The gas inside the chamber 1 is discharged to the outside of the chamber 1 through the gas discharge pipe 25.

The substrate supporting apparatus 30 includes the susceptor 31 on which the Substrate Sb is placed, and the moving mechanism 32 connected to the susceptor 31 and rotating the susceptor 31 around the central axis C of the susceptor 31 extending vertically. The moving mechanism 32 further moves the susceptor 31 in the direction in which the imaginary horizontal plane (XY plane) perpendicular to the central axis C extends. In this embodiment, the plasma CVD equipment 100 is provided with sets S of the chambers 1, the susceptors 31 and the moving mechanisms 32. In the example shown in FIG. 2, two sets S (S1, S2) are provided. However, the present invention is not limited to this, and three or more (for example, four) sets S may be provided.

The susceptor 31 is arranged inside the chamber 1. The susceptor 31 has a disc shape centered on the central axis C. The Substrate Sb is placed on the upper surface of the susceptor 31. The susceptor 31 may have a heating element inside so as to function as a heater during film formation. The susceptor 31 is made of a highly thermally conductive material. The susceptor 31 is made of, for example, a metal material such as aluminum, and is specifically made of aluminum nitride or the like.

As shown in FIG. 2 and the sub-panel (a) and (b) in FIG. 3, the moving mechanism 32 has the post 33, the external gear 34, and the internal gear 35. The post 33 is arranged below the susceptor 31 and supports the susceptor 31. The post 33 has a columnar shape extending in the vertical direction. The upper end of the post 33 is connected to the lower center of the susceptor 31. The post 33 is inserted into the through-hole 18 opening in the bottom wall of the chamber body 11. The post 33 extends through the inside and outside of the chamber 1 through the through hole 18.

The external gear 34 and the internal gear 35 are arranged below the chamber 1. That is, the external gear 34 and the internal gear 35 are arranged outside the chamber 1. The external gear 34 has an annular plate shape centered on the gear central axis A1. The external gear 34 has the teeth 34a arranged on its inner circumference. The teeth 34a are arranged side by side at equal pitches in the circumferential direction of the external gear 34 around the gear central axis A1. In the example shown in the sub-panel (a) and (b) in FIGS. 3, 12 teeth 34a are provided on the inner circumference of the external gear 34.

The internal gear 35 has a disc shape centered on the gear central axis A2. As shown in the sub-panel (a) and (b) in FIG. 3, the gear central axis A2 of the internal gear 35 is arranged at the position shifted from the gear central axis A1 of the external gear 34 when viewed in the vertical direction. That is, the gear central axis A2 of the internal gear 35 and the gear central axis A1 of the external gear 34 are arranged eccentrically to each other.

The lower end of the post 33 is connected to the upper center of the internal gear 35. The internal gear 35 is connected to the susceptor 31 via the post 33. The internal gear 35, post 33 and susceptor 31 are fixed to each other. The gear central axis A2 of the internal gear 35 and the central axis C of the susceptor 31 are arranged coaxially with each other.

The internal gear 35 has the teeth 35a arranged on its outer periphery. The teeth 35a are arranged side by side at equal pitches in the circumferential direction of the internal gear 35 around the gear central axis A2. The number of teeth of the internal gear 35 (the number of teeth 35a) is smaller than the number of teeth of the external gear 34 (the number of teeth 34a). Specifically, in this embodiment, the number of teeth of the internal gear 35 is one less than the number of teeth of the external gear 34. In the example shown in the sub-panel (a) and (b) in FIG. 3, 11 teeth 35a are provided on the outer periphery of the internal gear 35.

In this embodiment, the external gear 34 is fixed to the lifting mechanism 40 and does not rotate. The internal gear 35 is connected to the output shaft 52 (described later) of the gear mechanism 50 and rotates while meshing with the external gear 34. That is, the internal gear 35 rotates in the circumferential direction along the inner circumference of the external gear 34 while maintaining a state of meshing with the external gear 34.

Specifically, in the state shown in the sub-panel (a) in FIG. 3, the gear central axis A2 of the internal gear 35 is located on the front side (−Y side) of the gear central axis A1 of the external gear. From this state, when the internal gear 35 rotates along the inner circumference of the external gear 34, the gear central axis A2 of the internal gear 35 rotates around the gear central axis A1 of the external gear 34, and the position moves to the rear side (+Y side) of the gear central axis A1 of the external gear 34 as shown in the sub-panel (b) in FIG. 3. The internal gear 35 further rotates along the inner circumference of the external gear 34 to reach the state shown in the sub-panel (a) in FIG. 3.

In this manner, the gear central axis A2 of the internal gear 35 revolves around the gear central axis A1 of the external gear. Further, when the internal gear 35 rotates along the inner circumference of the external gear 34, the internal gear 35 rotates according to the difference between the number of teeth of the external gear 34 and the number of teeth of the internal gear 35. It rotates around the gear central axis A2. In this embodiment, when the internal gear 35 revolves around the inner circumference of the external gear 34, it rotates by one tooth.

Since the internal gear 35 revolves and rotates with respect to the external gear 34, the susceptor 31 connected to the internal gear 35 also rotates while revolving within the chamber 1. Specifically, when the internal gear 35 and the susceptor 31 revolve 180° around the gear central axis A from the sub-panel (a) to the sub-panel (b) in FIG. 3, the susceptor 31 moves forward and backward by the distance D (in the Y-axis direction). Although not shown in drawings, when the internal gear 35 and the susceptor 31 revolve 180° around the gear central axis A1 180° in a state where the phase (rotational angle) of the internal gear 35 and the susceptor 31 about the gear central axis A1 is shifted by 90° with respect to the sub-panels (a) and (b) in FIG. 3, the susceptor 31 moves a distance D in the left-right direction (X-axis direction).

Specifically, an arbitrary point on the susceptor 31 traces a trochoid curve-shaped movement locus within the horizontal plane (XY plane). Thus, the susceptor 31 is movable in the direction in which the horizontal plane extends.

Further, as shown in FIG. 2, the space between the bottom wall of the chamber body 11 and the external gear 34 is air-tightly sealed by the seal member 26 that is vertically expandable. Between the portion of the external gear 34 located above the teeth 34a and the portion of the internal gear 35 located above the teeth 35a, there is a seal that can expand and contract in the direction in which the horizontal plane (XY plane) extends. It is air-tightly sealed by member 27. A space between the internal gear 35 and the post 33 is air-tightly sealed by a sealing member 28 such as an O-ring.

The drive source 65 is, for example, a motor. The drive source 65 drives the lifting mechanism 40. The lifting mechanism 40 is driven by the drive source 65 to move the susceptor 31 vertically via the moving mechanism 32. Specifically, when the Substrate Sb is loaded into or unloaded from the chamber 1, the elevating mechanism 40 lowers the susceptor 31 to the lower end position. Further, when the film formation process is performed on the Substrate Sb by the CVD method, the elevating mechanism 40 elevates the susceptor 31 to the upper end position shown in FIG. 1.

During film formation, the raw material gas is ejected toward the Substrate Sb from the vent holes 21 of the shower head 20, and a high frequency (RF) voltage is applied between the shower head 20 and the upper surface (substrate mounting surface) of the susceptor 31; and the raw material gas is brought into a plasma state. As a result, active excited molecules, radicals, and ions are generated, chemical reactions are promoted, and a thin film is formed on the surface of the Substrate Sb.

As shown in FIG. 2, the drive source 65 also drives the internal gear 35 to rotate. The gear mechanism 50 transmits the rotational driving force of the drive source 65 to the internal gear 35. The gear mechanism 50 has the input shaft 51 to which the rotational driving force of the drive source 65 is input, and the output shafts 52 to which the rotational driving force input to the input shaft 51 is branched and output. In this embodiment, two output shafts 52 (52A, 52B) are provided. The internal gear 35 of the moving mechanism 32 of each set S (S1, S2) and each output shaft 52 (52A, 52B) are connected.

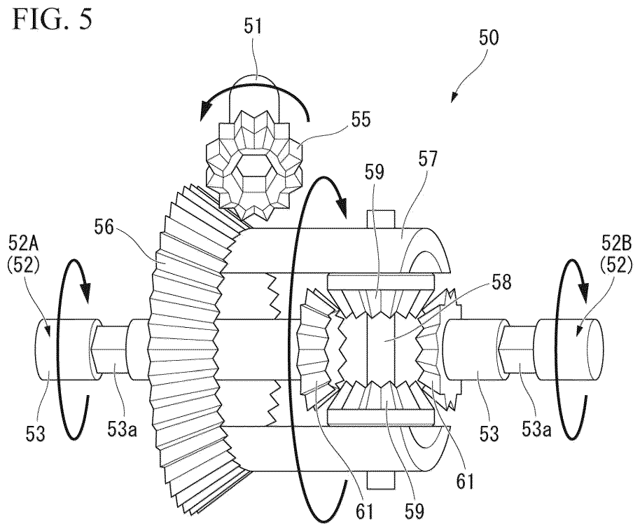

The output shaft 52 has the horizontal shaft portion 53 and the vertical shaft portion 54. The horizontal shaft portion 53 extends in the direction perpendicular to the vertical direction. In the illustrated example, the horizontal shaft portion 53 extends in the X-axis direction. As shown in FIGS. 5 and 6, the horizontal shaft portion 53 has the locking portion 53a that is locked with the locking mechanism 70. The locking portion 53a has a non-circular cross section perpendicular to the central axis of the horizontal shaft portion 53, and in this embodiment, it has a polygonal columnar shape such as a quadrangular columnar shape. In FIG. 2, illustration of the locking portion 53a and the locking mechanism 70 is omitted.

As shown in FIG. 2, the vertical shaft portion 54 extends vertically. The vertical shaft portion 54 and the horizontal shaft portion 53 are connected via a pair of bevel gears 62 and 63 that mesh with each other. The central axis of the vertical shaft portion 54 and the gear central axis A2 of the internal gear 35 are parallel to each other and arranged eccentrically. The central axis of the vertical shaft portion 54 is arranged coaxially with the gear central axis A1 of the external gear 34.

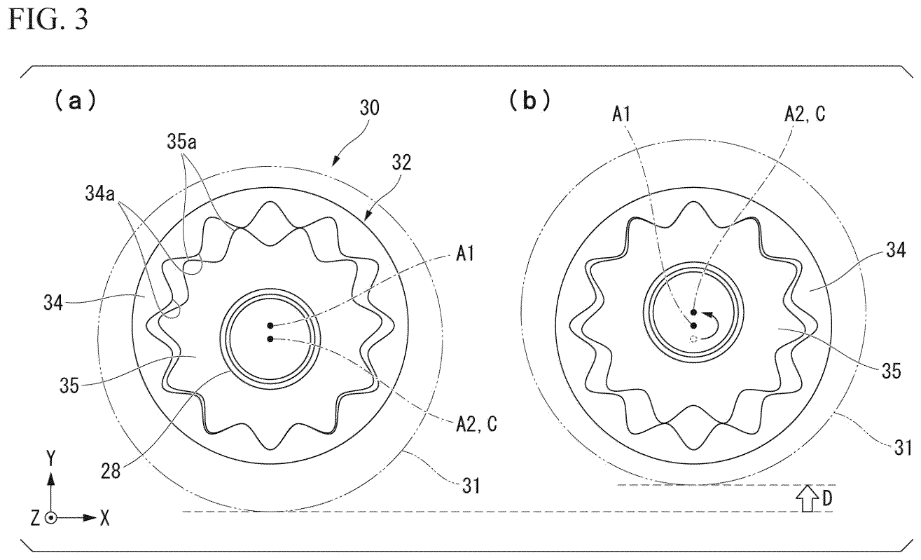

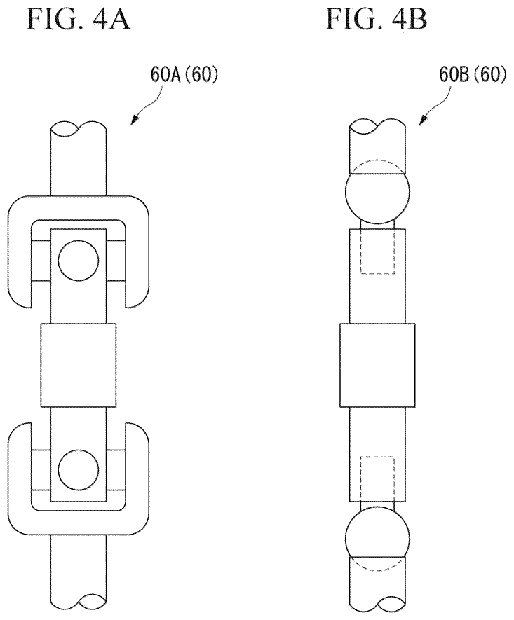

The connecting member 60 connects the internal gear 35 and the output shaft 52. Specifically, the connecting member 60 connects the internal gear 35 and the vertical shaft portion 54 which are arranged eccentrically. The connecting member 60 is configured by, for example, the universal joint 60A shown in FIG. 4A, the ball joint 60B shown in FIG. 4B, and the like. The connecting member 60 and the internal gear 35 are connected via a bearing (not shown) or the like.

As shown in FIG. 5, the gear mechanism 50 further has the input gear 55, the ring gear 56, the gear housing 57, the pinion shaft 58, the pinion gear 59, and the side gear 61.

The input gear 55 is provided on the input shaft 51. The ring gear 56 meshes with the input gear 55. The ring gear 56 has more teeth than the input gear 55 has. The gear housing 57 is fixed to the ring gear 56. The pinion shaft 58 is supported by the gear housing 57. The pinion shaft 58 extends in the direction orthogonal to the central axis of the ring gear 56 (radial direction of the ring gear 56).

A pair of pinion gears 59 are provided on the pinion shaft 58. The pair of pinion gears 59 are spaced apart from each other in the radial direction of the ring gear 56. Each pinion gear 59 is rotatably supported on a pinion shaft 58.

A pair of side gears 61 are provided on the output shafts 52A and 52B. Each side gear 61 is fixed to the horizontal shaft portion 53 of each output shaft 52A, 52B. The pair of side gears 61 mesh with a pair of pinion gears 59. The number of teeth of the pinion gear 59 and the number of teeth of the side gear 61 are the same. Each horizontal shaft portion 53 of the pair of output shafts 52A and 52B is arranged coaxially with the central axis of the ring gear 56.

In the gear mechanism 50, when the rotational driving force is input from the driving source 65 to the input shaft 51, this rotational driving force is converted into rotational driving force around the central axis of the ring gear 56 via the input gear 55 and the ring gear 56. The gear housing 57, the pinion shaft 58 and the pair of pinion gears 59 rotate about the central axis of the ring gear 56 by the ring gear 56 being rotated about its central axis.

When the pair of pinion gears 59 rotate (revolve) around the central axis of the ring gear 56, the pair of side gears 61 meshing with the pair of pinion gears 59 rotate around the central axis of the ring gear 56. As a result, the output shafts 52A and 52B to which the side gears 61 are fixed are rotationally driven around the central axis of the ring gear 56. In this way, the rotational driving force input to the input shaft 51 is branched and output to (a pair of) output shafts 52. The rotation speed of the output shaft 52 is determined by the gear ratio between the input gear 55 and the ring gear 56. By making the number of teeth of the ring gear 56 larger than the number of teeth of the input gear 55 as in the present embodiment, the rotational speed of the output shaft 52 can be kept low.

As shown in FIG. 6, the locking mechanism 70 can be locked to the locking portion 53a of the output shaft 52. Although not shown in the drawings, in this embodiment, a pair of lock mechanisms 70 are provided so as to face the locking portions 53a of the pair of output shafts 52A and 52B. Each locking mechanism 70 is configured to be able to advance and retreat with respect to each locking portion 53a. The lock mechanism 70 restricts rotation of a predetermined output shaft 52A or 52B among the output shafts 52A and 52B. Only one lock mechanism 70 may be provided.

In the example shown in FIG. 6, the locking mechanism 70 is locked to the locking portion 53a of the output shaft 52B. As a result, the rotation of the output shaft 52B about the central axis is restricted, and the rotation of the internal gear 35 of the set S2 connected to the output shaft 52B is restricted, thereby rotating the susceptor 31 of the set S2 about the central axis C. And movement in the direction in which the horizontal plane (XY plane) widens is restricted (see FIG. 2). By using the lock mechanism 70, the susceptor 31 can be stopped at any position within the range of movement in the direction in which the horizontal plane extends.

Further, in FIG. 6, when the rotation of the output shaft 52B is stopped by the lock mechanism 70, the rotation of the side gear 61 provided on the output shaft 52B is also stopped. As a result, the pair of pinion gears 59 meshing with the side gear 61 rotate (revolve) about the central axis of the ring gear 56 and rotate (rotate) about the central axis of the pinion shaft 58. As a result, the rotational speed of the output shaft 52A is increased together with the side gear 61 provided on the output shaft 52A. Specifically, the number of rotations of the output shaft 52A is doubled when the lock mechanism 70 is engaged with the engagement portion 53a compared to when the lock mechanism 70 is not engaged with the engagement portion 53a.

According to the substrate supporting apparatus 30 and the plasma CVD apparatus 100 of this embodiment described above, the moving mechanism 32 connected to the susceptor 31 rotates (rotates) the susceptor 31 around the central axis C and moves the susceptor 31; and moves the susceptor 31 in the direction the imaginary horizontal plane (XY plane) perpendicular to the central axis C extends. Therefore, even if the distribution of plasma density, pumping efficiency, gas diffusion, etc. varies at each position of the Substrate Sb in the chamber 1, the film characteristics of the thin film formed on the substrate Sb can be made uniform. In particular, even when the peak of the distribution of plasma density, pumping efficiency, gas diffusion, etc. is near the center of the substrate Sb (that is, in a state of the normal distribution), the film characteristics are made uniform in the substrate (wafer) radial direction.

Further, in this embodiment, the susceptor 31 can be stopped at any position within the moving range in the direction in which the horizontal plane (XY plane) extends.

For example, when it is preferable to keep the susceptor 31 at any position in the horizontal plane (XY plane) in order to make the film properties of the thin film formed on the substrate Sb uniform, the susceptor 31 movement can be stopped. It is also possible to combine moving and stopping the susceptor 31 appropriately. The film characteristics of the thin film formed on the substrate Sb can be made more uniform.

Further, in the present embodiment, the moving mechanism 32 has the external gear 34 and the internal gear 35 that rotates while meshing with the external gear 34 and is connected to the susceptor 31. The number of teeth of the internal gear 35 is less than the number of teeth of the external gear 34.

In this case, when the internal gear 35 rotates with respect to the external gear 34 and the gear central axis A2 of the internal gear 35 rotates once (revolves) around the gear central axis A1 of the external gear 34, the internal gear 35 rotates (rotates) around the gear center axis A2 of the internal gear 35 by the difference in the number of teeth between the teeth 34a and 35a (one tooth in this embodiment). That is, the internal gear 35 rotates around the gear center axis A2 of the internal gear 35 while revolving around the gear center axis A1 of the external gear 34. Along with this, the susceptor 31 connected to the internal gear 35 also rotates while revolving within the chamber 1. Therefore, the susceptor 31 can be stably moved in the direction the horizontal plane (XY plane) extends; and the film characteristics of the thin film formed on the substrate Sb can be made uniform with little variation at each position of the substrate Sb.

In addition, in this embodiment, the external gear 34 and the internal gear 35 are arranged outside the chamber 1. In this case, for example, even if metal chips or the like are generated due to the meshing of the external gear 34 and the internal gear 35, the problem of contamination in the chamber I can be prevented.

Further, in this embodiment, the driving source 65 drives the lifting mechanism 40. Thereby, the lifting mechanism 40 lifts and lowers the susceptor 31 when the substrate Sb is loaded into and unloaded from the chamber 1. In this embodiment, the drive source 65 is used to drive the internal gear 35 to rotate. In order to rotationally drive the internal gear 35, for example, it is not necessary to provide a new motor or the like, and equipment costs can be reduced.

Further, in this embodiment, the gear mechanism 50 that transmits the rotational driving force of the drive source 65 to the internal gear 35 is provided. The gear mechanism 50 has the input shaft 51 to which the rotational driving force is input, and the output shafts 52 (52A, 52B) to which the rotational driving force input to the input shaft 51 is branched and output. The sets S (S1, S2) of the susceptor 31 and the moving mechanism 32 are provided, and the internal gears 35 of the moving mechanisms 32 of the sets S1, S2 are connected to the respective output shafts 52A, 52B.

In this case, the rotational driving force of the drive source 65 is branched by the gear mechanism 50, and the branched rotational driving force is transmitted from the output shafts 52 (52A, 52B) to the set S (S1, S1, S2) of the moving mechanisms (32) and the susceptors (31). A single drive source 65 can rotate and move the susceptors 31. A thin film with uniform film characteristics can be formed on each substrate Sb supported by the susceptors 31.

Further, in this embodiment, the internal gear 35 revolves around the gear central axis A1 of the external gear 34 and rotates around the gear central axis A2 of the internal gear 35. Since the internal gear 35 revolves, the gear central axis A2 of the internal gear 35 and the central axis of the vertical shaft portion 54 of the output shaft 52 (corresponding to the gear central axis A1) are arranged eccentrically with each other. By connecting the internal gear 35 and the vertical shaft portion 54, which are arranged with their center axes shifted, by the connecting member 60 such as the universal joint 60A or the ball joint 60B, the rotational driving force of the output shaft 52 can be stably transmitted to the internal gear 35.

Further, the gear mechanism 50 of the present embodiment has a structure of a so-called differential device (differential gear). By using the gear mechanism 50, the rotational driving force input from the drive source 65 to the input shaft 51 can be stably output to the pair of output shafts 52A and 52B.

Further, in this embodiment, the lock mechanism 70 is provided to restrict the rotation of a predetermined output shaft 52 among the output shafts 52.

In this case, by restricting the rotation of the predetermined output shaft 52 by the lock mechanism 70, the susceptor 31 connected to the output shaft 52 via the moving mechanism 32 can be stopped at any position within the horizontal plane (XY plane). By stopping the susceptor 31 at a desired position or by combining movement and stopping, the film properties of the thin film formed on the substrate Sb can be made more uniform.

It should be noted that the present invention is not limited to the above-described embodiments, and, for example, as described below, changes in configuration can be made without departing from the gist of the present invention.

In the above-described embodiment, the plasma CVD apparatus 100 is provided with two sets S of the chamber 1, the susceptor 31, and the moving mechanism 32, but the present invention is not limited to this. For example, four sets S may be provided.

In this case, the rotational driving force of the drive source 65 is branched into two by a T-angle (not shown) or the like, the branched rotational driving force is input to a pair of gear mechanisms 50, and (a pair of) outputs are generated from each gear mechanism 50. A rotational driving force is output to the shafts 52A and 52B. Thereby, each of the susceptors 31 of the four chambers 1 can be rotated around the central axis C by one drive source 65 and moved in the direction in which the horizontal plane (XY plane) extends.

Also, the number of the teeth 34a of the external gear 34 and the number of the teeth 35a of the internal gear 35 are not limited to the numbers described in the above embodiment. Also, the number of teeth of the internal gear 35 may be less than the number of teeth of the external gear 34 by two or more.

Further, for example, by setting the rotation direction of the motor, which is the drive source 65, to forward or reverse rotation, the rotation direction in which the internal gear 35 rotates can be set to forward rotation or reverse rotation. The rotation direction of the internal gear 35 around the gear central axis A2 may repeat forward and reverse rotation within an angle range of 180° or less around the gear central axis A2. By alternately reversing the direction of rotation of the internal gear 35 within an angle range of 180° or less, the film characteristics of the thin film formed on the substrate Sb can be made uniform at each position on the substrate Sb with less variation.

In the above-described embodiments, the film formation processing apparatus according to the present invention has been described by taking the plasma CVD equipment 100 as an example, but the film formation processing apparatus is not limited to the plasma CVD equipment 100. The substrate processing apparatus may be, for example, a thermal CVD equipment, a plasma ALD apparatus, a thermal ALD apparatus, or the like.

The present invention may combine the configurations described in the above-described embodiments and modifications without departing from the gist of the present invention, and addition, omission, replacement, and other modifications of the configuration are possible. Moreover, the present invention is not limited by the above-described embodiments and the like, but is limited only by the scope of the claims.

### INDUSTRIAL APPLICABILITY

According to the substrate supporting apparatus and the substrate processing apparatus of the present invention, the film properties of the thin film formed on the substrate can be stably uniformed. Therefore, it has industrial applicability.

### DESCRIPTION OF SYMBOLS

1: Chamber, 30: Substrate supporting apparatus, 31: Susceptor, 32: Moving mechanism, 34: External gear, 34a: Teeth, 35: Internal gear, 35a: Teeth, 40: Lifting mechanism, 50: gear mechanism, 51: Input shaft, 52 (52A, 52B): Output shaft, 54: Vertical axis part, 55: Input gear, 56: ring gear, 57: gear housing, 58: Pinion shaft, 59: Pinion gear, 60 (60A, 60B): connecting member, 61: Side gear, 65: drive source, 70: lock mechanism, 100: Plasma CVD device (film formation processing device), A1: Gear central axis of external gear, A2: Gear central axis of internal gear, C: Central axis of susceptor, S (S1, S2): set, Sb: Substrate.

1. A substrate supporting apparatus comprising:
a susceptor configured for a substrate to be place on; and
a moving mechanism that is connected to the susceptor and configured to rotate the susceptor about a central axis of the susceptor, the central axis extending in a vertical direction, wherein
the moving mechanism is configured to move the susceptor further in a direction extending in an imaginary horizontal plane perpendicular to the central axis.

2. The substrate supporting apparatus according to claim 1, wherein the susceptor is configured to be stopped at any position within a movement range thereof extending in the direction extending in the horizontal plane.

3. The substrate supporting apparatus according to claim 1, wherein
the moving mechanism comprises:
an external gear, tooth being placed side by side on an inner circumference thereof; and
an internal gear connected to the susceptor, tooth being placed side by side on an outer circumference thereof, the internal gear being configured rotate in a state where the tooth and the tooth meshing with each other, wherein
a number of teeth of the internal gear is less than a number of teeth of the external gear.

4. The substrate supporting apparatus according to claim 1, wherein any point on the susceptor traces a trochoidal curved trajectory on the imaginary horizontal plane.

5. A substrate processing apparatus comprising:
the substrate supporting apparatus according to claim 1; and
a chamber housing the susceptor.

6. A substrate processing apparatus comprising:
the substrate supporting apparatus according to claim 3;
a chamber housing the susceptor;
a lifting mechanism configured to move the susceptor vertically; and
a drive source configured to drive the lifting mechanism.

7. The substrate processing apparatus according to claim 6, wherein the external gear and the internal gear are placed outside the chamber.

8. The substrate processing apparatus according to claim 6, wherein the drive source is further configured to rotate the internal gear.

9. The substrate processing apparatus according to claim 6, wherein the internal gear is configured to repeat forward and reverse rotation within an angle range of 180° or less centered on a central axis of the internal gear in a rotation direction of the internal gear about the central axis.

10. The substrate processing apparatus according to claim 8, further comprising a gear mechanism configured to transmit a rotational driving force of the driving source to the internal gear, wherein
the gear mechanism comprises:
an input shaft configured for the rotational driving force to be input; and
a plurality of output shafts configured for the rotational driving force that is input to the input shaft and branched to be output,
a plurality of sets of the susceptor and the movement mechanism are provided, and
the internal gear of the moving mechanism of each of the sets is connected to each of the input shafts.

11. The substrate processing apparatus according to claim 10, further comprising a connecting member connecting the internal gear and the output shafts, wherein
the output shaft has a vertical shaft part extending in a vertical direction, and
the connecting member connects the internal gear and the vertical shaft part that are arranged eccentric to each other.

12. The substrate processing apparatus according to claim 10, wherein the gear mechanism comprises:
an input gear provided to the input shaft;
a ring gear configured to mesh with the input gear;
a gear housing fixed on the ring gear;
a pinion shaft supported by the gear housing;
a pair of pinion gears rotatably supported by the pinion shaft; and
a pair of side gears configured to mesh with the pair of the pinion gears, and
a pair of the output gears that are arranged coaxially with a central axis of the ring gear are provided, and
each of the side gears is provided to each of the output gears.

13. The substrate processing apparatus according to claim 12, wherein a number of teeth of the ring gears is larger than a number of teeth of the input gear.

14. The substrate processing apparatus according to claim 12, wherein a number of teeth of the pinion gears is identical to a number of teeth of the side gears.

15. The substrate processing apparatus according to claim 10, further comprising a lock mechanism configured to prevent rotation of one of the output shafts.

16. The substrate processing apparatus according to claim 6, wherein the substrate processing apparatus is a CVD equipment configured to deposit a thin film on the substrate by a CVD method.
